(19) United States
(12) Patent Application Publication
(10) Pub. No.: US 2019/0165328 A1
(43) Pub. Date: May 30, 2019

(54) DISPLAY PANEL AND MANUFACTURING METHOD THEREOF

(71) Applicant: Wuhan China Star Optoelectronics Semiconductor Display Technology Co., Ltd., Wuhan (CN)

(72) Inventor: Shijuan YI, Shenzhen (CN)

(21) Appl. No.: 15/969,354

(22) Filed: May 2, 2018

Related U.S. Application Data
(63) Continuation of application No. PCT/CN2018/071669, filed on Jan. 5, 2018.

(30) Foreign Application Priority Data
Nov. 30, 2017 (CN) 201711247587.6

(51) Int. Cl. H01L 51/56; H01L 27/32

(52) U.S. Cl. CPC H01L 51/56; H01L 27/3244

(57) ABSTRACT

A display panel and manufacturing method thereof are provided. The method of manufacturing display panel includes following steps. Providing a carrier substrate, the carrier substrate comprises a plurality functional region and a cutting region positioned between the functional regions; forming an element layer on the carrier substrate, the element layer comprises a TFT element and an inorganic layer encapsulated the TFT element, the TFT element is positioned on the functional region, and the inorganic layer covering the functional regions and the cutting regions; removing the inorganic layer on the cutting region, and forming a plurality of TFT element region and grooves positioned between the TFT element regions; cutting the carrier substrate along the groove and forming a plurality of display panel.

### RELATED APPLICATIONS

This application is a continuation application of PCT Patent Application No. PCT/CN2018/071669, filed Jan. 5, 2018, which claims the priority benefit of Chinese Patent Application No. 201711247587.6, filed Nov. 30, 2017, which is herein incorporated by reference in its entirety.

### FIELD OF THE DISCLOSURE

The disclosure relates to a display technical field, and more particularly to a display panel and manufacturing method thereof.

### BACKGROUND

AMOLED (Active-matrix organic light emitting diode) has number of advantageous such as self-luminous, wide view angle, high color saturation, especially low driving voltage and fast response, light, thin, simple structure and low cost. Therefore, the AMOLED become the most important future display product.

While manufacturing the AMOLED display panel, in order to decrease the produce cost, manufacturing a plurality of display panel on large substrate to form a display panel mother substrate and then cutting the display panel mother substrate to form each of display panel unit. In the cutting process of the AMOLED display panel, because of the to-be cutting film usually formed by inorganic layer such as SiNx, SiOx. The inorganic layer is thick, easy to produce stress acclamation in cutting process such that brock or have cracks, the cracks spread to the packaging region of the AMOLED display panel or periphery wire region or display region, there will causes failure of manufacturing the AMOLED display panel and decreasing product yield of AMOLED display panel.

### SUMMARY

A technical problem to be solved by the disclosure is to provide a method of manufacturing display panel with increased product yield.

The method of manufacturing display panel provided by this disclosure, comprising

providing a carrier substrate, the carrier substrate comprises a plurality functional region and a cutting region positioned between the functional regions;

forming an element layer on the carrier substrate, the element layer comprises a TFT element and an inorganic layer encapsulated the TFT element, the TFT element is positioned on the functional region, and the inorganic layer covering the functional regions and the cutting regions;

removing the inorganic layer on the cutting region, and forming a plurality of TFT element region and grooves positioned between the TFT element regions:

cutting the carrier substrate along the groove and forming a plurality of display panel.

In an embodiment, in the step of removing the inorganic layer on the cutting region is according to the mask exposing, development and etching process.

In an embodiment, after the step of removing the inorganic layer on the cutting region, forming a channel on the inorganic layer of edge of the TFT element region, the channel is extending along the groove, the channel is for blocking cutting stress of the groove.

In an embodiment, in the step of forming the channel on the inorganic layer of edge of the TFT element region is according to the mask exposing, development and etching process.

In an embodiment, after the step of removing the inorganic layer on the cutting region, comprising

depositing an organic layer, the organic layer is filling the channel and covering the element layer;

removing the organic layer on the cutting region according to the mask exposing, development and etching process.

In an embodiment, in the step of providing the carrier substrate, the carrier substrate includes a first organic film, a first inorganic film, a second organic film and a second inorganic film are positioned on the carrier substrate.

In an embodiment, in the step of removing the inorganic layer on the cutting region, partially or totally removing the second inorganic film.

According to another aspect of the disclosure, the disclosure further provides a display panel, comprising a carrier substrate, and an element layer positioned on the carrier substrate, wherein the carrier substrate comprises a functional region, and a cutting region positioned on periphery of the functional region, the element layer comprises a TFT element region is faced to the functional region, and an empty region is facing to the cutting region.

In an embodiment, edge of the TFT element region further comprises a channel, the channel is extending along the edge of the TFT element region, the channel for blocking cutting stress of the empty region.

In an embodiment, the display panel comprises an organic layer positioned on the element layer, the organic layer is filling the channel and covering the element layer.

The display panel and manufacturing method thereof in this disclosure, according to remove the inorganic layer which is corresponding to the cutting region of the carrier substrate for thinning the inorganic layer of the cutting region. On one side, thickness of the cutting film layer is decreased which is decreases difficult of cutting process; on another side, while the inorganic layer is become thin, it effectively alleviates problem of stress concentration of cutting process, enhances product yield of display panel and also remove the inorganic layer to form groove. The groove could be a cutting line during cutting process such that enhances effectiveness of cutting the display panel.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a flow chart diagram of a method of manufacturing display panel according to an embodiment of the disclosure;

FIG. 2 is a structural schematic view of step S101 of the method of manufacturing display panel of the disclosure;

FIG. 3 is a structural schematic view of step S101 of the method of manufacturing display panel of the disclosure;

FIG. 4 is a structural schematic view of step S102 of the method of manufacturing display panel of the disclosure;

FIG. 5 is a structural schematic view of step S103 of the method of manufacturing display panel of the disclosure;

FIG. 6 is a structural schematic view of step S104 of the method of manufacturing display panel of the disclosure;

FIG. 7 is a structural schematic view of step S103 of the method of manufacturing display panel of the disclosure;

FIG. 8 is a structural schematic view of step S1031 of the method of manufacturing display panel of the disclosure;

FIG. 9 is a structural schematic view of step S1031 of the method of manufacturing display panel of the disclosure;

FIG. 10 is a structural schematic view of step S1030 of the method of manufacturing display panel of the disclosure;

FIG. 11 is a structural schematic view of step S1030 of the method of manufacturing display panel of the disclosure;

FIG. 12 is a structural schematic view of step S1031 of the method of manufacturing display panel of the disclosure; and

FIG. 13 is a structural schematic view of a display panel according to embodiment of the disclosure.

### DETAILED DESCRIPTION OF PREFERRED EMBODIMENTS

In order to understand the above purposes, features and advantages of this disclosure more clearly, next, this disclosure will be described in more details with reference to the drawings and detailed description. It should be noted that in the case of not conflicting, the embodiments of the present application and the features in the embodiments can be combined with one another.

The specific structural and functional details disclosed herein are only representative and are intended for describing exemplary embodiments of the disclosure. However, the disclosure can be embodied in many forms of substitution, and should not be interpreted as merely limited to the embodiments described herein.

In addition, the following description of embodiments with reference to the attached diagram for illustrating particular embodiments may be used to embodiments of the present disclosure. Term direction of the present disclosure are mentioned, for example, “top”, “bottom”, “upper”, “lower”, “front”, “rear”, “left”, “right”, “inside”, “outside”, “side” and so on, only with reference to the accompanying drawings, direction, and thus, the direction of terms used in order to better and more clearly illustrate the present disclosure and understanding, rather than indicating device or element or imply referred to must have a specific orientation, with particular orientation construction and operation, and therefore cannot be construed as limiting the present disclosure.

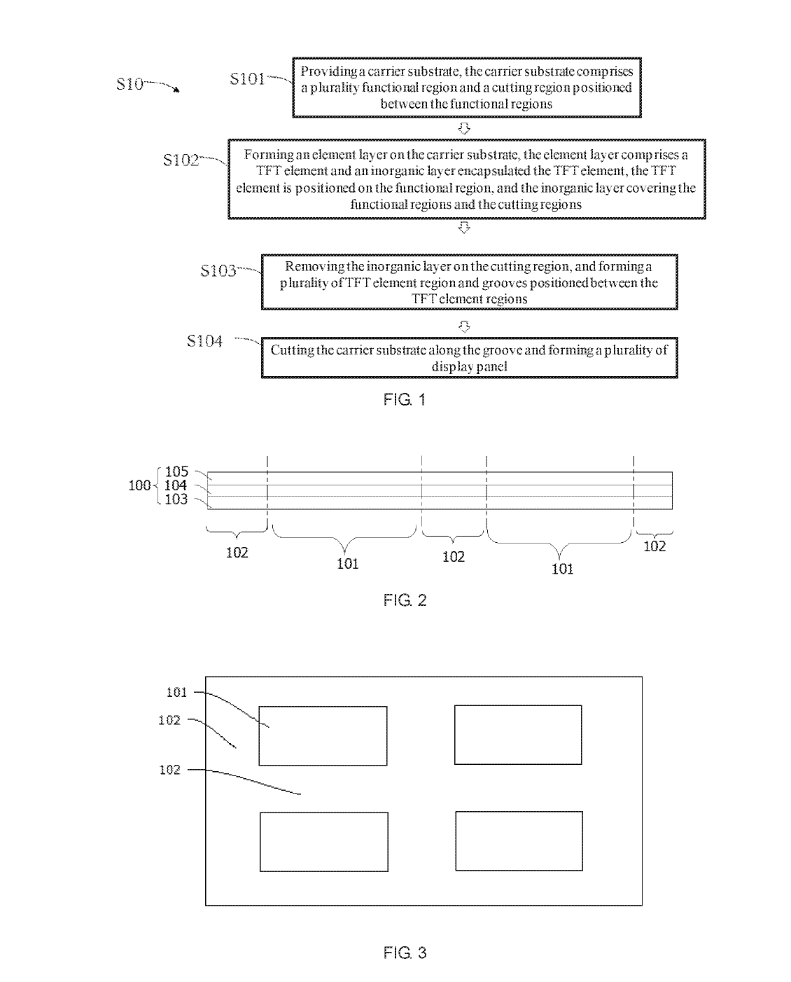

Please refer to FIG. 1. FIG. 1 is a method of manufacturing display panel S10 according to embodiment of this disclosure. It could be understood, the display panel includes but not limited by LCD, OLED and so on display panel. In this disclosure illustrated by AMOLED display panel. The method of manufacturing display panel S10 is related to display panel cutting method. During manufacturing AMOLED display panel, in order to decrease cost, it could prepare a plurality of display panels in larger size substrate and forming mother plate of display panel. And then cutting the mother plate to form display panels such that achieves to mass production of display panel, and enhances yield of product.

The AMOLED display panel includes a carrier substrate and a multi-films layer positioned on the carrier substrate. The multi-film layer comprising a blocking layer, a TFT element layer, an OLED element layer and a packaging layer are sequentially stacking positioned. While cutting the multi-film layer, most of the cutting film layer is made by inorganic film such as SiNx, SiOx, the inorganic film is thick and worse flexibility such that easy produce stress accumulation in cutting process and broken or have crack. While the crack spread to the peripherally wire of the AMOLED display panel, it will seriously effect image quality and cause Mura of image display. While the crack spread to the GOA region of the AMOLED display panel, the TFT element of the GOA will invalid, and causes GOA invalided such that display panel cannot be bright. While the crack is nearby the groove will causes a serious problem of thin film package, let the water-oxygen easy to enter the display panel and decreases yield of display panel.

Please refer to FIG. 1, the method of manufacturing display panel S10, comprises the following steps.

S101, please refer to FIG. 2 and FIG. 3. Providing a carrier substrate 100, the carrier substrate 100 comprises a plurality functional region 101 and a cutting region 102 positioned between the functional regions 101. The functional region 101 is for positioning display element and wire for driving the display element. The cutting region 102 is positioned outside the functional region 101, and does not have element and circuit. Selectively, the functional region 101 is rectangle; the cutting region 102 is grid shaped. During the following process, cutting along the cutting region 102 could divide a plurality of display panel unit.

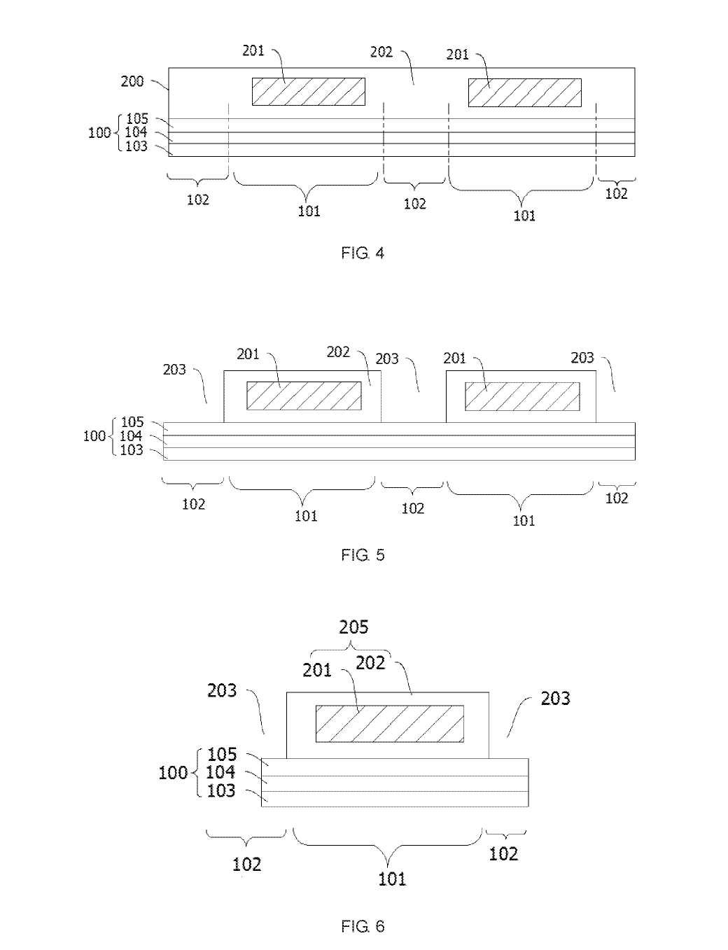

S102, please refer to FIG. 4. Forming an element layer 200 on the carrier substrate 100. The element layer 200 comprises a TFT element 201 and an inorganic layer 202 encapsulated the TFT element 201. The TFT element 201 is positioned on the functional region 101. The inorganic layer 202 is covering the functional regions 101 and the cutting region 102.

S103, please refer to FIG. 5. Removing the inorganic layer 202 on the cutting region 102, and forming a plurality of TFT element region 205 and grooves 203 are positioned between the TFT element regions 205.

S104, please refer to FIG. 6. Cutting the carrier substrate 100 along the groove 203 and forming a plurality of display panel.

In this embodiment, removing the inorganic layer 202 which is corresponding to the cutting region 102 on the carrier substrate 100 for thinning the inorganic layer 202 of the cutting region 102. On one aspect, thickness of the cutting film layer is decreased, and reduces difficult of cutting process; on another aspect, while thinning the inorganic layer 202, it effectively alleviates the problem of stress concentration in the cutting process, and enhance yield of display panel. At the same time, removing the inorganic layer 202 to form groove 203, the groove 203 could be a cutting line during cutting process such that enhance effectiveness of cutting display panel.

The disclosure will be further described in detail with reference to accompanying drawings and preferred embodiments as follows.

In step S101, please refer to FIG. 2 and FIG. 3, providing a carrier substrate 100. The carrier substrate 100 could be a substrate for compositing the multi-film layer of AMOLED display panel. The carrier substrate 100 could be flexible substrate.

In another embodiment, the carrier substrate 100 includes a first organic film 103, a first inorganic film 104, a second organic film 105 and a second inorganic film 106 are positioned on the carrier substrate 100. Wherein, the first organic film 103 and the second organic film 105 achieving bendable and flexible of the carrier substrate 100 by cross linking according to heating process.

Selectively, material of the first organic film 103 and the second organic film 105 is one of or composite by poly(ethylene naphthalate) (PEN), polyethylene terephthalat (PET), PI polyimide (PI) and parylene. Preferably, material of the first organic film 103 and the second organic film 105 is polyimide.

Because the first organic film 103 and the second organic film 105 have high water vapor transmission rate, and it effect stability property and lifetime of the TFT element 201 and the OLED element. Preferably, the carrier substrate 100 using the first organic film 103, the first inorganic film 104, the second organic film 105 and the second inorganic film 106 are alternatively positioned to form the blocking layer. Wherein, materials of the first inorganic film 104 and the second inorganic film 106 is made by one or more of the SiNx and SiOxNy. The inorganic film has good structure density and provides to block water, oxygen function such that enhances water-oxygen blocking property function of the carrier substrate 100, it effectively protecting the TFT element 201 and the OLED element. Using to position the organic film and the inorganic film at interval not only achieves to protect blocking, but also eliminates the stress effect between each of protecting materials. The double layers of inorganic film could provide double functions to block water, oxygen. Because the flat of the surface of the inorganic film is not enough, depositing second organic film 105 could provide the function of flatting the surface. The second inorganic film 106 further be a blocking heating layer could effectively be blocking heat transduction, and avoid to effect whole element manufacture problem from the unstable carrier substrate 100 after high temperature treating.

In another embodiment, the second inorganic film 106 has organic film and inorganic film are alternatively positioned. The number of the organic film and inorganic film of the carrier substrate 100 is not limited.

In step S102, please refer to FIG. 4. Forming the element layer 200 on the carrier substrate 100. The TFT element 201 of the element layer 200 is correspondingly positioned the functional region 101. The cutting region 102 which is corresponding to the TFT element layer 200 is inorganic layer 202.

Specifically, the TFT element 201 of the element layer 200 includes a grid, a source and a drain. The inorganic layer 202 includes a multi-layer insulating layer, for example, a first grid insulting layer, a second grid insulating layer, a grid and a layer insulating layer positioned between the data lines. The material of these insulating layers is one of or two of composition by SiOx and SiNx. These insulating layers have high density, worse flexibility such that easy to concentrate the stress. It hinders the cutting process. In this disclosure, these insulating layers are called inorganic layer 202 of the element layer 200.

In step S103, please refer to FIG. 5. Removing the inorganic layer 202 on the cutting region 102, and forming a plurality of TFT element region 205 and grooves 203 positioned between the TFT element regions 205.

In the first probably embodiment, coating photoresist on the element layer 200 and then removing the inorganic layer 202 on the cutting region 102 by the mask exposing, development and etching process. Patterning the element layer 200 and forming a plurality of TFT element region 205 and grooves 203 located between the TFT element regions 205. The element region 205 is used for positioned the TFT element 201 and the wires. The TFT element region 205 is facing to the functional region 101, and the projection of the TFT element region 205 on the carrier substrate 100 is overlapping the functional region 101. The groove 203 is facing to the cutting region 102. Selectively, width of the groove 203 is 50˜100 um. The distance between two adjacent TFT element regions 205 is 50˜100 um

According to remove the inorganic layer 202 on the cutting region 102 which could reduce cutting resistance of the cutting region 102 for decreasing effect of cutting process by the inorganic layer 202 on the cutting region 102. At the same time, only using one photolithography which could remove the inorganic layer 202 on the cutting region 102, easy manufacture and easy to operate and has obvious effectiveness.

In this embodiment, the carrier substrate 100 includes a first organic film 103, a first inorganic film 104, a second organic film 105 and a second inorganic film 106. Wherein, the second inorganic film 106 is positioned nearby the inorganic layer 202 of the element layer 200. The second inorganic film 106 also will cause the stress concentration while cutting process and the problem of generated cracks.

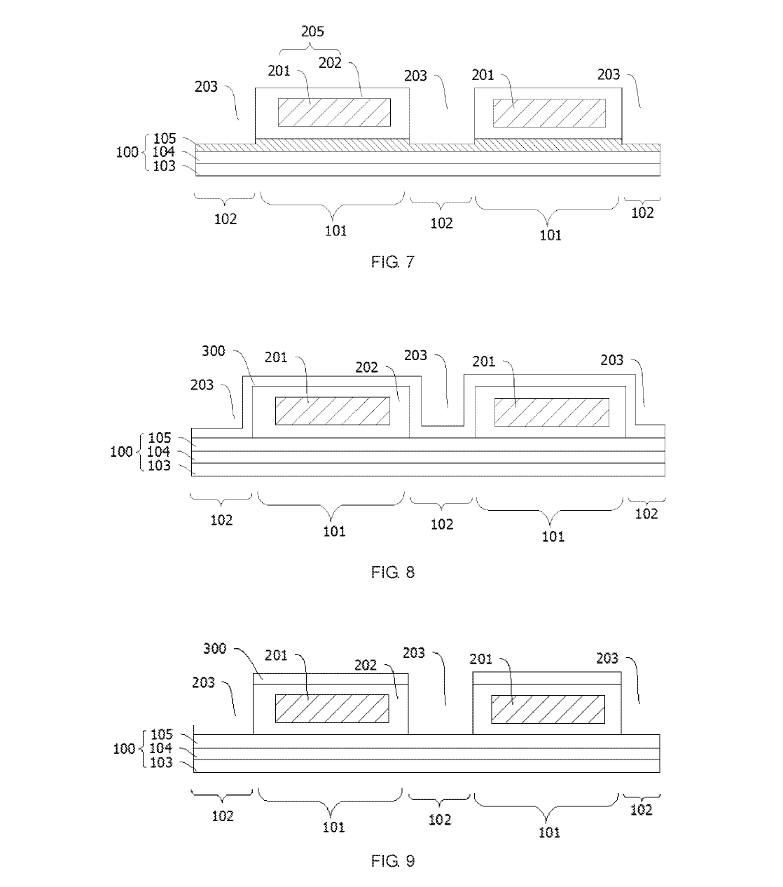

In the second probably embodiment, please refer to FIG. 7. Coating photoresist on the element layer 200 and then removing the inorganic layer 202 on the cutting region 102 by the mask exposing, development and etching process, and thinning or totally removing the second inorganic film 106. Patterning the element layer 200 to form a plurality of TFT element region 205 and grooves 203 located between the TFT element regions 205.

Comparing with the first embodiment, thickness of the to-be cutting layer is less that this embodiment. Especially the thickness of the inorganic layer 202 of the to-be cutting layer is decreased. Therefore, it could further decrease problem of stress concentration, cracks generated of the cutting region 102 while cutting process such that enhances product yield of display panel. At the same time, because of the first inorganic film 104, the carrier substrate 100 still has a better property of blocking water-oxygen, it also enhances cutting effect of display panel while ensure the property of blocking water-oxygen in carrier substrate 100.

After the step S103, the method manufacturing of display panel S10 further comprises following steps.

In step S1031, please refer to FIG. 8 and FIG. 9, depositing an organic layer 300 on the element layer 200, removing the organic layer 300 which is corresponding to the cutting region.

Specifically, the organic layer 300 is used to prepare the OLED layer, such that the element layer 200 and the OLED layer are forming an AMOLED.

The OLED layer comprises a plurality of organic layers, for example a planar layer 301, an anode positioned on the planar layer 301, a light emitting region defining layer positioned on the anode, an organic light emitting layer is positioned on the anode and surrounding by the light emitting region defining layer, and a cathode is positioned on the organic light emitting layer and the light emitting region defining layer.

The anode, the organic light emitting layer and the cathode are facing to the functional region 101, which is positioned outside the cutting region 102. The planar layer 301 and the light emitting region defining layer are facing to the cutting region 102 and located in the groove 203. The organic layer 300 is the planar layer 301 and the light emitting region defining layer.

In another embodiment, removing the organic layer on the cutting region 102 according to the mask exposing, development and etching process. Which is removing the planar layer 301 and the light emitting region defining layer are positioned on the cutting region 102 according to the mask exposing, development and etching process for decreasing thickness of the to-be cutting layer, and reducing effect of cutting process by the planar layer 301 and the light emitting region defining layer.

In the third probably embodiment, after step S103 of removing the inorganic layer 202 of the cutting region 102, before the step S131 of depositing the organic layer on the element layer 200 further comprises following steps.

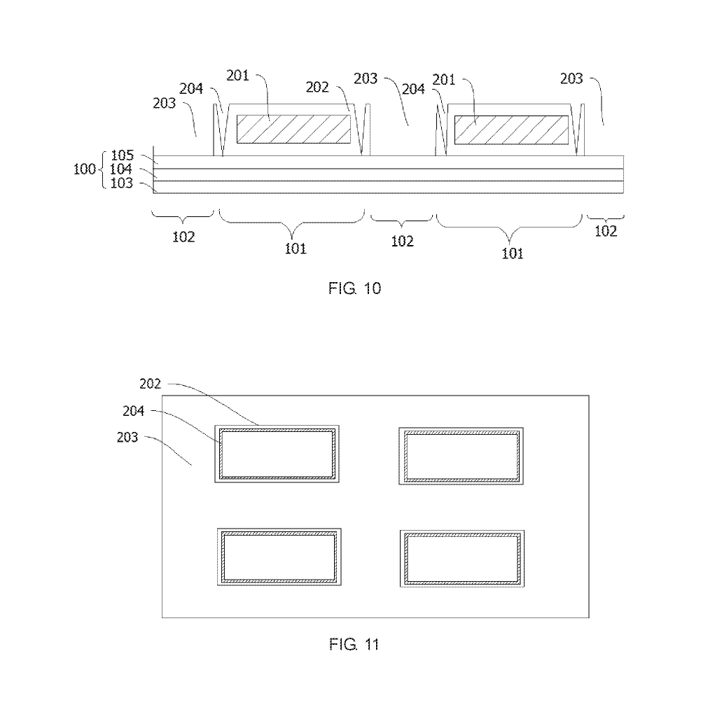

In step S1030, please refer to FIG. 10 and FIG. 11. Forming a channel 204 on the inorganic layer 202 of edge of the TFT element region 205. The channel 204 is extending along the groove 203. The channel 204 is for blocking cutting stress of the groove 203.

In a probably embodiment, according coating photoresist on the element layer 200 and removing the inorganic layer 202 on the cutting region 102 according to the mask exposing, development and etching process, patterning the element layer 200 to form the channel 204 on the element layer 200. The channel 204 could pass the element layer 200. The channel 204 could separate the TFT element 201, the wire and the inorganic layer 202 which adjacent to the cutting region 102. While cutting the display panel, the cutting region 102 generating crack, the crack is extending toward to TFT element 201 by the inorganic layer 202 and direction of the wire. At this time, the channel could block extending path of the crack such that effectively protect TFT element 201 and wire, and prevent the TFT element 201 and wire are damaged by the cutting crack. It is said that, the disclosure could reduce stress concentration by decreases thickness of to-be cutting layer such that decreases crack generated. At the same time, the channel 204 is for blocking crack path. In this embodiment, the groove 203 and the channel 204 are used to be double protecting way of the TFT element 201 and the wire, it effectively decreases the stress concentration, crack of the cutting region 102 while cutting process, and the stress damage issue of the TFT element 201 and the wire. Therefore, it could improve product yield production of display panel.

In another embodiment, the step S1031 of depositing the organic layer on the element layer 200, further comprises following steps.

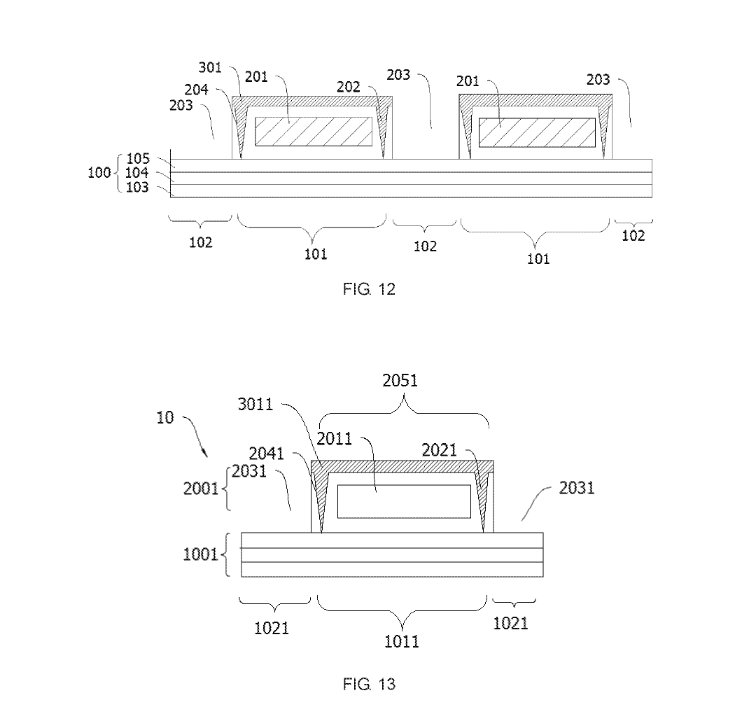

Please refer to FIG. 12, the OLED layer includes the planar layer 301. The planar layer 301 could fill the channel 204. The planar layer 301 is made by organic material, which has better flexible and elastic, could better release of stress. According to form the channel 204 in the inorganic layer 202 and fill the planar layer 301 therein could improve stress property of inorganic layer 202, preventing the stress concentration, crack generated issue of display panel while cutting process, and enhances quality of flexible AMOLED display panel.

In step S104, cutting the carrier substrate 100 along the groove 203, and forming a plurality of display panel.

Using laser to cut the carrier substrate 100 along the groove 203, and it could along central line of the groove 203 for cutting the carrier substrate 100 such that the effect region by laser of the carrier substrate 100 is located on the cutting region 102, and won't affect the functional region 101, it enhances cutting effectiveness of the display panel. At the same time, positioning the groove 203 make the TFT element 201 and wire won't be affected by laser, and also enhances production yield of display panel.

Please refer to FIG. 13. A display panel 10 is provided by this disclosure, made by the method described above. The display panel 10 includes a carrier substrate 1001 and an element layer 2001 is positioned on the carrier substrate 1001. The carrier substrate 1001 comprises a functional region 1011, and a cutting region 1021 positioned on periphery of the functional region 1011. The element layer 2001 comprises a TFT element region 2051 is faced to the functional region 1011, and an empty region 2031 is facing to the cutting region 1021. The TFT element region 2051 further comprises a TFT element 2011, a wire for driving the TFT element 2011 and an inorganic layer for encapsulating the TFT element 2011 and the wire. The TFT element region 2051 is projecting on the functional region 1011 of the carrier substrate 1011. The empty region 2031 is surrounding the lateral of the TFT element region 2051.

According to position the TFT element region 2051 is facing the functional region 1011 and the empty region 2031 is facing the cutting region of the carrier substrate 1001 for decreasing thickness of the inorganic layer corresponding to the cutting region 1021. On one aspect, the thickness of the cutting film layer is decreased such that decreasing difficult of cutting process; on another aspect, decreasing thickness of inorganic layer which is corresponding to the cutting region 1021 such that effectively alleviative problem of stress concentration of cutting process and enhances production yield of display panel 10.

In another embodiment, please refer to FIG. 13. The edge of the TFT element region 2051 further comprises a channel 2041. The channel 2041 is located in the inorganic layer of the TFT element region 2051. The channel 2041 is extending along the empty region 2031. The channel 2041 is for blocking the cutting stress of the empty region 2031. The channel 2041 is positioning for blocking crack path, the empty region 2031 and the channel 2041 is positioned to be double protecting way of the TFT element 2011 and the wire. It could effectively decrease the stress concentration, crack generated on the cutting region 1021 during the cutting process and the stress damage of the TFT element 2011 and the wire, such that more improve product yield of display panel 10.

In a probably embodiment, please refer to FIG. 13. The display panel 10 includes an OLED layer positioned on the element layer 2001. The OLED layer includes an organic layer. The organic layer filling the channel 2041 and covering the element layer 2001. The organic layer could be planar layer 3011 of the OLED layer. The organic layer has better elastic and flexible could better release stress. According to form the channel 2041 and filling planar layer 3011 therein, could improve stress property of inorganic layer, prevent stress concentration, crack generated issue while cutting process of the display panel 10, such that enhances quality of the flexible AMOLED display panel 10.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A method of manufacturing display panel, comprising
providing a carrier substrate, the carrier substrate comprises a plurality functional region and a cutting region positioned between the functional regions;
forming an element layer on the carrier substrate, the element layer comprises a TFT element and an inorganic layer encapsulated the TFT element, the TFT element is positioned on the functional region, and the inorganic layer covering the functional regions and the cutting regions;
removing the inorganic layer on the cutting region, and forming a plurality of TFT element region and grooves positioned between the TFT element regions;
cutting the carrier substrate along the groove and forming a plurality of display panel.

2. The method of manufacturing display panel according to claim 1, wherein in the step of removing the inorganic layer on the cutting region is according to the mask exposing, development and etching process.

3. The method of manufacturing display panel according to claim 1, wherein after the step of removing the inorganic layer on the cutting region, forming a channel on the inorganic layer of edge of the TFT element region, the channel is extending along the groove, the channel is for blocking cutting stress of the groove.

4. The method of manufacturing display panel according to claim 3, wherein in the step of forming the channel on the inorganic layer of edge of the TFT element region is according to the mask exposing, development and etching process.

5. The method of manufacturing display panel according to claim 3, wherein after the step of removing the inorganic layer on the cutting region, comprising
depositing an organic layer, the organic layer is filling the channel and covering the element layer;
removing the organic layer on the cutting region according to the mask exposing, development and etching process.

6. The method of manufacturing display panel according to claim 1, wherein in the step of providing the carrier substrate, the carrier substrate includes a first organic film, a first inorganic film, a second organic film and a second inorganic film are positioned on the carrier substrate.

7. The method of manufacturing display panel according to claim 6, wherein in the step of removing the inorganic layer on the cutting region, partially or totally removing the second inorganic film.

8. A display panel, comprising
a carrier substrate, and
an element layer positioned on the carrier substrate,
wherein the carrier substrate comprises a functional region, and a cutting region positioned on periphery of the functional region, the element layer comprises a TFT element region is faced to the functional region, and an empty region is facing to the cutting region.

9. The display panel according to claim 8, wherein edge of the TFT element region further comprises a channel, the channel is extending along the edge of the TFT element region, the channel for blocking cutting stress of the empty region.

10. The display panel according to claim 9, where the display panel comprises an organic layer positioned on the element layer, the organic layer is filling the channel and covering the element layer.
